(19) United States
(12) Patent Application Publication
(10) Pub. No.: US 2026/0300687 A1
(43) Pub. Date: Oct. 1, 2026

(54) ADAPTIVE OSCILLATOR PHYSICAL RESERVOIR COMPUTER

(71) Applicant: Edmon Perkins, Cary, NC (US)

(72) Inventor: Edmon Perkins, Cary, NC (US)

(21) Appl. No.: 19/489,002

(22) PCT Filed: May 31, 2024
(86) PCT No.: PCT/US2024/032107

§ 371 Date: Dec. 1, 2025

Related U.S. Application Data
(60) Provisional application No. 63/470,390, filed on Jun. 1, 2023.
(60) Provisional application No. 63/546,656, filed on Oct. 31, 2023.

(51) Int. Cl. G06N 3/044; G06N 3/063; H03K 19/20

(52) U.S. Cl. CPC G06N 3/044; G06N 3/063; H03K 19/20

(57) ABSTRACT

Various examples are provided related to adaptive oscillator physical reservoir computers. In one example, a physical reservoir computer (PRC) comprises an adaptive oscillator (AO) including a dynamic plastic state adaptable to a corresponding input function. The PRC can utilize the dynamic plastic state to perform reconfigurable tasks. The AO can include multiple dynamic plastic states each adaptable to a corresponding input function. For example, the dynamic plastic state can correspond to a frequency state, an amplitude state, or a phase state of an input. The AO-based PRC can operate without time or spatial multiplexing. Thus, the AO PRC can function as an analog signal processor of the external signal, compute reprogrammable machine learning tasks, or function as a morphable logic gate.

### CROSS REFERENCE TO RELATED APPLICATIONS

This application claims priority to, and the benefit of, U.S. provisional applications entitled “Adaptive Oscillator Physical Reservoir Computer” having Ser. No. 63/470,390, filed Jun. 1, 2023, and Ser. No. 63/546,656, filed Oct. 31, 2023, both of which are hereby incorporated by reference in their entireties.

### BACKGROUND

Neuromorphic computing is a computing paradigm that takes inspiration from biological neurons. Physical reservoir computers (PRCs) repurpose the nonlinear dynamics of a physical system for computation. PRCs were a natural progression of non-physical reservoir computers, which are deep neural networks that have hidden layers with untrained weights. Growing from echo state networks and liquid state machines, reservoir computing has several advantages, including lower training costs and robustness to overfitting. Notably, PRCs differ from traditional Turing machines, as the information storage is not static. Physical reservoir computers have been employed for a wide variety of tasks, including digit recognition (written and spoken), image recognition, prediction of time series, and logic operations. Physical reservoir computers have been created from optoelectronics, soft robots, tensegrities, the Duffing oscillator array, quantum systems, and limit cycle oscillators.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 illustrates an example of two periodic orbits in an x−y−ω state space for an adaptive oscillator, in accordance with various embodiments of the present disclosure.

FIG. 2 illustrates an example of the dynamics of the adaptive oscillator for a normalized, time-varying external force, in accordance with various embodiments of the present disclosure.

FIG. 3 illustrates an example of an example of heart ECG signal prediction, in accordance with various embodiments of the present disclosure.

FIG. 4A illustrates an example of speech prediction and FIG. 4B illustrate an example of image recognition, in accordance with various embodiments of the present disclosure.

FIG. 5 illustrates examples of logic task results, in accordance with various embodiments of the present disclosure.

FIGS. 6-10 illustrate examples of parametric studies using an XOR task as a benchmark, in accordance with various embodiments of the present disclosure.

FIG. 11 is a circuit schematic illustrating an example of an adaptive oscillator physical reservoir computer, in accordance with various embodiments of the present disclosure.

FIG. 12 illustrates an example of a response of the adaptive oscillator physical reservoir computer, in accordance with various embodiments of the present disclosure.

FIG. 13 illustrates an example of operational range of a field-programmable analog array (FPAA) circuit configured to implement the adaptive oscillator physical reservoir computer, in accordance with various embodiments of the present disclosure.

FIG. 14 illustrates an example of an example of an adaptive oscillator physical reservoir computer performing a one-step-ahead heart ECG signal prediction task, in accordance with various embodiments of the present disclosure.

FIG. 15 illustrates an example of an adaptive oscillator physical reservoir computer performing a one-step-ahead speech prediction task, in accordance with various embodiments of the present disclosure.

FIGS. 16A and 16B illustrate examples of parametric studies using an XOR task as a benchmark, in accordance with various embodiments of the present disclosure.

FIG. 17 is a circuit schematic illustrating an example of an adaptive oscillator physical reservoir computer, in accordance with various embodiments of the present disclosure.

FIG. 18 illustrates an example of operational range of a FPAA circuit configured to implement the adaptive oscillator physical reservoir computer, in accordance with various embodiments of the present disclosure.

FIG. 19 illustrates an example of a response of the adaptive oscillator physical reservoir computer, in accordance with various embodiments of the present disclosure.

FIGS. 20A and 20B illustrate an example of the time history of the adaptive oscillator PRC, in accordance with various embodiments of the present disclosure.

FIG. 21 illustrates an example of the adaptive oscillator acting as an AND (∧) gate, in accordance with various embodiments of the present disclosure.

FIG. 22 illustrates an example of the adaptive oscillator acting as an OR (∨) gate, in accordance with various embodiments of the present disclosure.

FIG. 23 illustrates an example of the adaptive oscillator acting as a NOT (¬) gate, in accordance with various embodiments of the present disclosure.

FIG. 24 illustrates an example of an adaptive oscillator physical reservoir computer producing a morphable logic gate bit stream, in accordance with various embodiments of the present disclosure.

FIG. 25 illustrates an example of a response of the adaptive oscillator physical reservoir computer, in accordance with various embodiments of the present disclosure.

FIG. 26 illustrates examples of the adaptive oscillator physical reservoir computer acting as AND, OR and NOT gates, in accordance with various embodiments of the present disclosure.

FIGS. 27A and 27B illustrates examples of relationships between system parameters of the adaptive oscillator physical reservoir computer acting as AND and OR gates, in accordance with various embodiments of the present disclosure.

FIG. 28 is a circuit schematic illustrating an example of an adaptive oscillator physical reservoir computer, in accordance with various embodiments of the present disclosure.

FIG. 29 illustrates an example of the time history of the adaptive oscillator PRC, in accordance with various embodiments of the present disclosure.

FIG. 30 illustrates an example of the echo state property index of the adaptive oscillator PRC, in accordance with various embodiments of the present disclosure.

### SUMMARY

Aspects of the present disclosure are related to adaptive oscillator physical reservoir computers. In one aspect, among others, a physical reservoir computer (PRC) comprises an adaptive oscillator (AO) including a dynamic plastic state adaptable to a corresponding input function, the PRC configured to utilize the dynamic plastic state to perform reconfigurable tasks. In one or more aspects, the AO can comprise a plurality of dynamic plastic states each adaptable to a corresponding input function. The dynamic plastic state can correspond to a frequency state of an input. The frequency state can learn a resonance condition from the input. The AO can comprise a second dynamic plastic state corresponding to an amplitude state of the input. The AO can comprise a second dynamic plastic state corresponding to a phase state of the input. The frequency state of the adaptive oscillator can correspond to a sampling rate of the desired task. In various aspects, an external forcing signal based upon encoded data can be injected into the AO. The external forcing signal can be generated by multiplying a sinusoid with an encoded information stream comprising the encoded data. The PRC can utilize time multiplexing or the PRC does not utilize time multiplexing. The PRC can be a Hopf adaptive oscillator, a van der Pol adaptive oscillator, a pendulum adaptive oscillator, a linear adaptive oscillator, a piecewise linear adaptive oscillator, a Duffing adaptive oscillator, a Rayleigh adaptive oscillator, or a neural adaptive oscillator. The physical reservoir computer can comprise a morphable logic gate wherein the AO is a single AO. The morphable logic gate can be configured to determine a plurality of logic operations without modifying circuitry of the single AO. The morphable logic gate can be configured to determine at least two of the plurality of logic operations in parallel with the single AO. An analog signal processor can comprise the physical reservoir computer as described in any of these aspects. A reprogrammable neural network can comprise the physical reservoir computer as described in any of these aspects. A morphable logic gate can comprise the physical reservoir computer as described in any of these aspects.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described embodiments are usable in all aspects of the disclosure taught herein. Furthermore, the individual features of the dependent claims, as well as all optional and preferred features and modifications of the described embodiments are combinable and interchangeable with one another.

### DETAILED DESCRIPTION

Disclosed herein are various examples related to adaptive oscillator physical reservoir computers. Reference will now be made in detail to the description of the embodiments as illustrated in the drawings, wherein like reference numbers indicate like parts throughout the several views.

Physical reservoir computing is usually composed of three parts: the input that is an external forcing that acts to perturb the nonlinear system, the reservoir (e.g., the physical system itself), and the readout function that is usually trained with a simple machine learning approach, such as a ridge regression. While physical reservoir computers employ machine learning to unlock their computational ability, adaptive oscillators have an innate ability to both learn and store information in dynamic plastic states. Adaptive oscillators are a subset of nonlinear oscillators. Although relatively little work has explored these oscillators, they have many potential applications. Adaptive oscillators can act as an analog frequency analyzer by learning an external forcing frequency. The Hopf adaptive oscillator can be implemented as a printed circuit board and as a field-programmable analog array circuit, and its frequency analysis capabilities can be benchmarked with a range of tasks. When the base oscillator is a pendulum, it was found that adaptive oscillators can learn a resonance condition, which is not the external forcing frequency. Importantly, this resonance-learning can be utilized for energy harvesting purposes, without the need of a digital frequency analysis. Adaptive oscillators have also been used for central pattern generators, robotic locomotion control, medical gait analysis, and an analog signal analyzer capable of learning multiple frequencies. It should be noted that plasticity at the synaptic level often is incorporated into spiking neural networks, with a comprehensive review of this topic provided by “Bottom-up and top-down neural processing systems design: Neuromorphic intelligence as the convergence of natural and artificial intelligence” by C. Frenkel et al. However, this type of plasticity has not been implemented for physical reservoir computing previously.

For the Hopf physical reservoir computer, it was found that its computational abilities are enhanced by resonance criteria. Arnold tongues are synchronization regions that appear in the nonlinear oscillator, which re-appear in the Hopf physical reservoir computer as regions of high computation. Numbers from the Farey sequence also appear when studying the synchronization of a nonlinear oscillator with an external force, and this Farey sequence is also mirrored in the computational ability of the Hopf physical reservoir computer. This disclosure presents the creation of robust physical reservoir computers by taking advantage of resonance criteria. However, it also poses a significant challenge, as these resonance conditions exist under rather precise frequencies. For Arnold tongues, robustness is gained at the cost of an amplified signal, which increases the energy requirements.

There are multiple types of plasticity in neuromorphic computing. At the neuronal level, spike-frequency adaptation is governed by the relationship between a neuron's spiking rate and a steady state stimulus. This is quite different than an adaptive oscillator's dynamics, as the neuron itself is not learning information but only exhibiting different responses based on external stimuli. The adaptive oscillator, on the other hand, is learning and storing information in a plastic state. When an array of spiking neurons are coupled with synapses, they form a spiking neural network. Spiking neural networks have another type of plasticity, in which the synapses can be modified to store information.

In physical reservoir computing, the dynamic response of a nonlinear system can be used as a computational resource by applying machine learning techniques. Related to physical reservoir computers (PRCs), non-physical reservoir computers are constructed from deep neural networks with some hidden layers (i.e., the reservoir) that have random, untrained weights. Reservoir computing came from liquid state machines and echo state networks. Since PRCs do not have static information storage, they are different from Turing machines. Many different time dependent systems have been explored as physical reservoir computers. These include the Hopf oscillator, memristors, a Duffing array, quantum reservoir networks, superparamagnetic tunnel junctions, an array of linear oscillators, spintronics, lasers in special mediums, microelectromechanical systems, and the nonlinear response of materials.

On the other hand, adaptive oscillators are a subset of nonlinear oscillators that can learn and store information in dynamic plastic states. For instance, the Hopf adaptive frequency oscillator has two states that correspond to the non-adaptive Hopf oscillator, while the remaining state can learn and store an external forcing frequency. This can be extended to include states for amplitude or more complex waveforms. Since linear vibratory energy harvesters employ resonance to boost performance and nonlinear harvesters use nonlinearity to increase bandwidth, adaptive oscillators may be ideal vibratory energy harvesters since they can track resonance (e.g., the pendulum adaptive frequency oscillator). Interestingly, adaptive oscillators can also exhibit chaotic motion for certain parameter combinations.

Oscillator-based physical reservoir computers typically employ time multiplexing to create virtual nodes. For vibrating systems, this is a seemingly necessary step to capture the necessary information from the system, as computing and memory storage are both provided by the oscillator itself. This is cumbersome from a practical perspective, as it requires a faster sampling rate than the clock frequency. However, for a physical reservoir computer composed of an adaptive oscillator, time multiplexing can be completely avoided. In this case, the adaptive oscillator's response at a single instance per clock cycle directly provides the calculation of different logic gates. Interestingly, this approach creates a reprogrammable logic gate, without the necessity of modifying the adaptive oscillator itself.

As comparison, nonlinear oscillators have also been used for reprogrammable logic gates, in which the dynamics of the oscillator were modified to correspond as different gates. For instance, a bistable oscillator's asymmetry can be tuned to produce different logic gates, lattices of coupled chaotic maps set a critical value to function as different gates, and a Duffing oscillator can be used as a reprogrammable logic gate by incorporating a feedback controller. The present adaptive oscillator PRC utilizes the complex dynamic response of the oscillator to avoid modifying the oscillator itself (i.e., no feedback or parameter tuning is necessary). At the same time, machine learning is used to reprogram the non-multiplexed response to correspond to different logic gates using a single sample per clock cycle.

In this disclosure, a new architecture of a physical reservoir computer is presented, which uses an adaptive oscillator as the reservoir. Notably, the adaptive oscillator itself is a neuromorphic computer, which is capable of certain learning and memory storage tasks without any training or processing. Unlike the plasticity in neurons discussed above, the adaptive oscillator learns and stores a value in a plastic state. Using this adaptive oscillator, the reservoir itself is capable of learning resonance conditions that increase its power as a physical reservoir computer. Further, this adaptive oscillator physical reservoir computer has no synapses, so the oscillator's adaptive states are the only source of plasticity for this system. This form of dual learning could overcome the previous limitations of limit cycle oscillator-based reservoir computers. Furthermore, this reservoir-level learning unlocks the potential of the physical reservoir computer to be used for applications with a wide range of frequencies. For instance, the same physical reservoir computer could be used for both low frequency and high frequency applications, such as gait analysis and audio recognition tasks, respectively.

### Equations for the Adaptive Oscillator Physical Reservoir Computer

In this section, the equations of motion for the Hopf oscillator, Hopf-based adaptive frequency oscillator, and the Hopf-based adaptive frequency oscillator physical reservoir computer will be discussed. Similar results can be achieved using other adaptive oscillators as the base for the physical reservoir computer.

The classical Hopf oscillator is presented first for completeness:

$$\dot{x} = ( μ - ( {x}^{2} + {y}^{2} ) ) x - {ω}_{0} y \qquad ( 1 )$$

$$\dot{y} = ( μ - ( {x}^{2} + {y}^{2} ) ) y + {ω}_{0} x$$

The Hopf oscillator is a limit cycle oscillator. When μ is positive, there is one unstable point, [0,0], while all other parameter combinations of [x,y] will coalesce to a limit cycle. A limit cycle is an isolated periodic solution, which has no other periodic solutions close to it. The Hopf oscillator shown in eq. (1) has one limit cycle. It should be noted that limit cycles require nonlinearity, and oscillators that exhibit limit cycles are often called limit cycle oscillators.

Expanding on the classical Hopf oscillator, the Hopf-based adaptive frequency oscillator is described by the following equation:

$$\dot{x} = ( μ - ( {x}^{2} + {y}^{2} ) ) x - ω y + k ( f ( t ) ) \qquad ( 2 )$$

$$\dot{y} = ( μ - ( {x}^{2} + {y}^{2} ) ) y + ω x$$

$$\dot{ω} = - k ( f ( t ) ) y$$

In eq. (2), f(t) is a time-varying external force (e.g., a normalized, time-varying external force) that acts on the adaptive oscillator. This adaptive oscillator has a Hopf oscillator as its base (e.g., x and y). In eq. (1), the Hopf oscillator has a constant resonance parameter, ω₀, while the adaptive oscillator in eq. (2) has a dynamic frequency state, ω. When this adaptive oscillator is forced with a sinusoid, such as sin(Ωt), the ω state will converge to Ω.

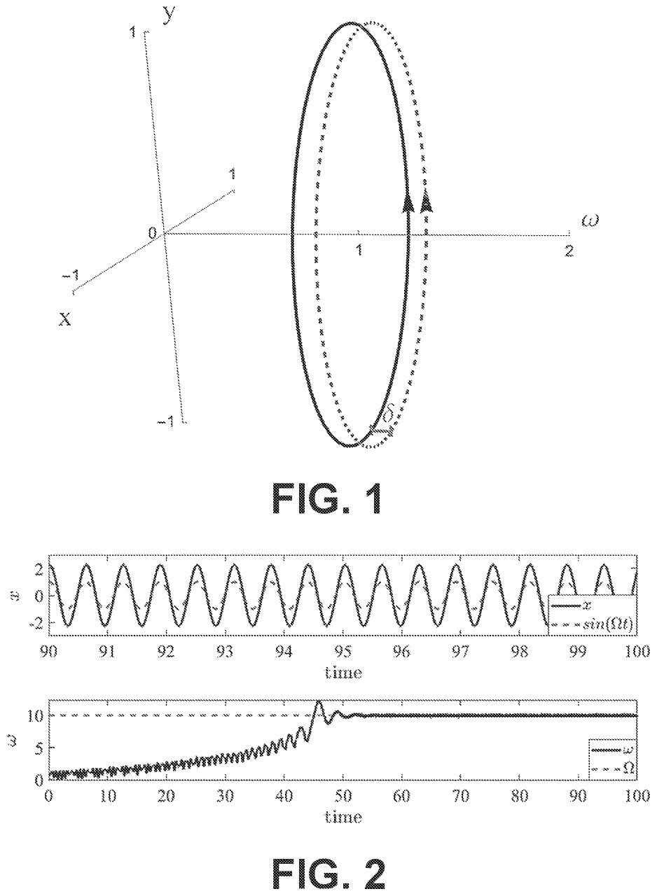

Interestingly, the adaptive oscillator shown in eq. (2) is not a limit cycle oscillator (like a regular Hopf oscillator). This can be easily seen by choosing two sets of initial conditions, [x₀,y₀,ω₀] and [x₀,y₀,ω₀+δ], where the first set of initial conditions are chosen to correspond to a closed periodic orbit and δ>0 is an arbitrary constant. For any ϵ>0, a δ can be chosen such that ϵ>δ>0. This implies that the second set of initial conditions is arbitrarily close to the first set of initial conditions, so the adaptive oscillator cannot have isolated periodic solutions. The only difference in the two orbits described by these two sets of initial conditions is the resonance frequency, which is governed by the ω state. In the three-dimensional state space, x−y−ω, they are shifted only an amount S in the ω direction. For an adaptive oscillator, two periodic orbits are shown in the x−y−ω state space in FIG. 1. They are separated by an amount, S, in the ω direction. By varying S, the two orbits can be made arbitrarily close to each other, which shows that the adaptive oscillator does not have limit cycles. A local stability analysis of the Hopf-based adaptive frequency oscillator shows that the x and y states have a stable periodic solution that oscillates with a frequency of ω, but ω itself is neither stable nor unstable.

The adaptive oscillator given by eq. (2) can be used as a physical reservoir computer. As the ω state innately learns and stores vibratory information, it can be leveraged as a dual learning system that leverages reservoir-level learning to better exploit the physical reservoir computing architecture. In FIG. 2, an example of the dynamics of the adaptive oscillator is shown for reference for the case that f(t)=sin(Ωt). The adaptive oscillator can learn and store information in its dynamic plastic state, ω. The x state of the adaptive oscillator becomes synchronized to the external sinusoid, while the ω state plastically deforms to the external forcing frequency, Ω. Although the ω state learns this value, Ω only interacts with ω through the forcing function (i.e., it is not known a priori by the adaptive oscillator). In the example of FIG. 2, a sinusoid with a frequency of 10 rad/s is used to force the adaptive oscillator. The x state synchronizes with the external force, and the ω state learns and stores this external frequency. Further, if a more complex function for f(t) is used, the ω state will learn the dominant frequency. For instance, if f(t) is a square wave, the ω state will learn the fundamental frequency.

The adaptive oscillator can now be further modified to incorporate an additional external force, which encodes information to be processed:

$$\dot{x} = ( μ ( g ( t ) + 1 ) ) - ( {x}^{2} + {y}^{2} ) ) x - ω y + k ( f ( t ) ) \qquad ( 3 )$$

$$\dot{y} = ( μ ( g ( t ) + 1 ) - ( {x}^{2} + {y}^{2} ) ) y + ω x$$

$$\dot{ω} = - k ( f ( t ) ) y$$

g(t) is a continuous function, which is constructed from a discrete function, h(z). g is equal to a value of h for a length of time equal to the pseudo-period, Tₚ. Tₚ is an arbitrary length of time, which is used to also define a pseudo-period as

$${ω}_{p} = \frac{2 π}{{T}_{p}} .$$

The continuous function is defined as:

$$g ( t ) = h ( {z}_{n} ) for ( n ) {T}_{p} \leq t < ( n + 1 ) {T}_{p} , n ∈ {ℤ}^{+} \qquad ( 4 )$$

Thus, g(t) holds the value of h(zₙ) for a single pseudo-period. For logic tasks, h(z) is composed of a random series of −1 (e.g., “False”) and +1 (e.g., “True”) values. For other time series tasks, h(z) is normalized. Its magnitude is scaled in eq. (3) by the μ constant.

During each pseudo-period, virtual nodes can be collected from the y state. These virtual nodes can be collected into a matrix. Next, a simple ridge regression can be used to train this matrix to a particular task. For the simulations and experiments shown here, 100 virtual nodes were collected, a regularization penalty of 0.001 was used for the ridge regression, 80% of the data was used for training, and the remaining 20% was used for testing.

### Benchmarking Tasks

Notably, physical systems oscillate at considerably different time scales, which necessitates vastly different sampling rates. For instance, the human heart can be monitored with a smart watch, and the heart's range is often between 40 and 140 beats per minute. With this low frequency, heart data can be sampled at a relatively low rate. On the other hand, human speech has information content in the range from approximately 100 Hz to 3000 Hz (with the higher harmonics being mostly only useful in a musical context). Thus, speech requires a substantially higher sampling rate to preserve information. These different dynamic systems utilize different sampling rates, which necessitates different computational rates as well. To highlight the enhanced reconfigurability of the adaptive oscillator physical reservoir computer, the results for several benchmark tasks are shown, which include both heart and speech prediction tasks. Notably, the adaptive oscillator physical reservoir computer can be reconfigured at will to perform computation on various systems that need different sampling rates and computational speeds. As a real-world application, this physical reservoir computer can offer an ideal candidate for an edge computer that performs both heart monitoring and speech recognition tasks.

Heart ECG Prediction. A recording of a heart ECG signal from PhysioNet was used to perform a prediction task. This recording had a sampling rate of 1000 Hz, but it was downsampled to 250 Hz. This slower frequency can preserve much of the major features of the time history, but this more modest sampling rate could be more easily managed by wearables.

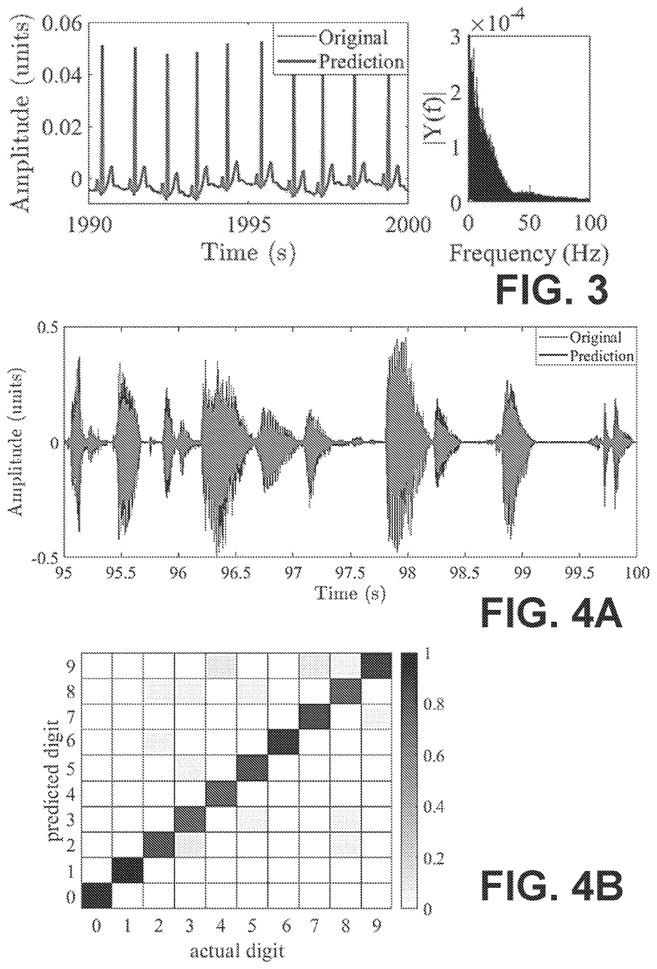

By setting the pseudo-period equal to this sampling rate and choosing Ω=2ωₚ, the resonance frequency of the adaptive oscillator adapts to the Ω value. This allows the adaptive oscillator physical reservoir computer to perform real-time processing on the heart data. FIG. 3 shows an example of the heart ECG signal prediction. By choosing a pseudo-period equal to the sampling rate, the adaptive oscillator physical reservoir computer can perform real-time prediction. A one-step-ahead heart ECG signal prediction was chosen. The RMSE for the test portion of this task was 0.054. μ=25, k=25, and N=10.

Speech Prediction. The spoken digit data set was composed of multiple individuals saying single digit numbers, which were recorded at a sampling rate of 8000 Hz. This sampling rate is a popular choice, as it is high enough to preserve information content of human speech, but it is low enough to allow for faster processing for voice recognition tasks.

Following the same procedure as discussed for the ECG digit data set, the pseudo-period is set to the sampling rate and Ω=2ωₚ. The resonance frequency of the adaptive oscillator adapts to the Ω value by allowing the adaptive oscillator physical reservoir computer to perform real-time processing on the audio data. FIG. 4A shows an example of the speech prediction. By choosing a pseudo-period equal to the sampling rate, the adaptive oscillator physical reservoir computer can perform real-time speech prediction. A one-step-ahead speech prediction was chosen. The RMSE for the test portion of this task was 0.032. μ=25, k=25, and N=10.

Image Recognition. The image processing capability of the physical reservoir computer was tested with a MNIST handwritten digit dataset. The images were first rescaled by ranging the pixel values between 0 and 1. Subsequently, a down sampling process was applied by performing a maximum pooling operation twice, resulting in a 7×7 pixel image. This image was flattened to a 1D vector and sent to the oscillator (i.e., the pixels of the image were sent to the oscillator sequentially). Unlike the other tasks, this image recognition task only used 10 virtual nodes for each pixel. The resulting confusion matrix is provided in FIG. 4B, which shows the reservoir's performance for digit recognition. A value of “1” corresponds to a perfect prediction, while each column sums to 1.

Logic Tasks. Logic tasks were also explored. A logical XOR task can be used for several parametric studies. For these logical tasks, the physical reservoir computer was first trained in the continuous domain. Next, the trained output in each pseudo-period was averaged to convert the continuous data to the discrete domain, and this averaged value was then rounded to +1 or −1.

For the logical task, the relevant metric is a modified version of Shannon's information rate. Comparing this to the original work, the correct output of the logical task acts as the “sent” signal, and the predicted output of the task from the physical reservoir computer acts as the “received” signal. The information rate can be written as:

$$IR = H ( x ) - {H}_{y} ( x ) \qquad ( 5 )$$

Here, H(x) is the Shannon entropy, and H_{y}(x) is the conditional entropy. The amount of information in a signal is calculated from the Shannon entropy, which sets an upper limit on the information rate. The probability of an incorrect bit is given by the conditional entropy. The probability of getting a particular bit, i, is written as pᵢ. Considering a bit i is from the target and a bit j is from the prediction, the conditional probability of target bit i and predicted bit j is:

$${p}_{i} ( j ) = p ( j \vert i ) = \frac{p ( i , j )}{{\sum }_{j} p ( i , j )} \qquad ( 6 )$$

The joint probability distribution of the two variables is p(i,j). Thus, the Shannon entropy and conditional entropy may be written as:

$$H ( x ) = - {\sum }_{i} {p}_{i} {log}_{2} ( {p}_{i} ) \qquad ( 7 )$$

$$and$$

$${H}_{y} ( x ) = - {\sum }_{i , j} p ( i , j ) {log}_{2} ( {p}_{i} ( j ) ) \qquad ( 8 )$$

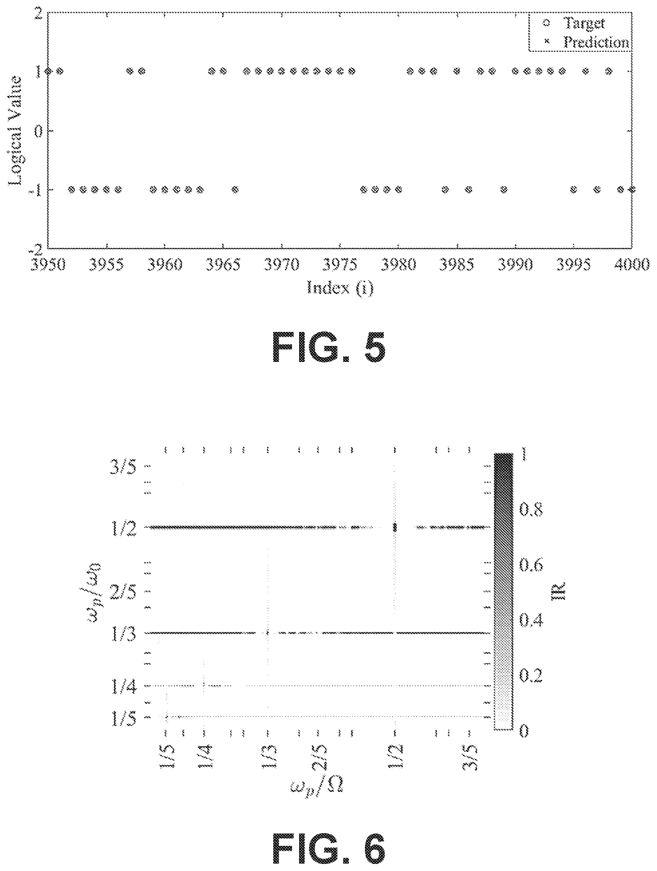

This modified Shannon's information rate is reported for all logic task benchmarks in this disclosure. A value of “IR=1” corresponds to a perfect prediction for the XOR task. FIG. 5 shows an example of the logic task results. Here, the adaptive oscillator physical reservoir computer calculates the exclusive OR task (XOR). The modified Shannon's information rate for the test portion of this task was equal to 1. ωₚ=20π Ω=2ωₚ, μ=5, k=5, and N=100.

### Parametric Studies

In this section, an XOR task will be used as a benchmark to quantify the behavior of both the Hopf physical reservoir computer and the adaptive oscillator physical reservoir computer. Previously, it was shown that frequency ratios taken from the Farey sequence play an important role in obtaining computational power for the Hopf physical reservoir computer. As reference, FIG. 6 shows the computational ability, as measured by the modified information rate, for the Hopf physical reservoir computer. Here, μ=5, k=5, and ωₚ=20π. As can be seen in FIG. 6, a slight mistuning in the static resonance value, ω₀, can result in poor functioning.

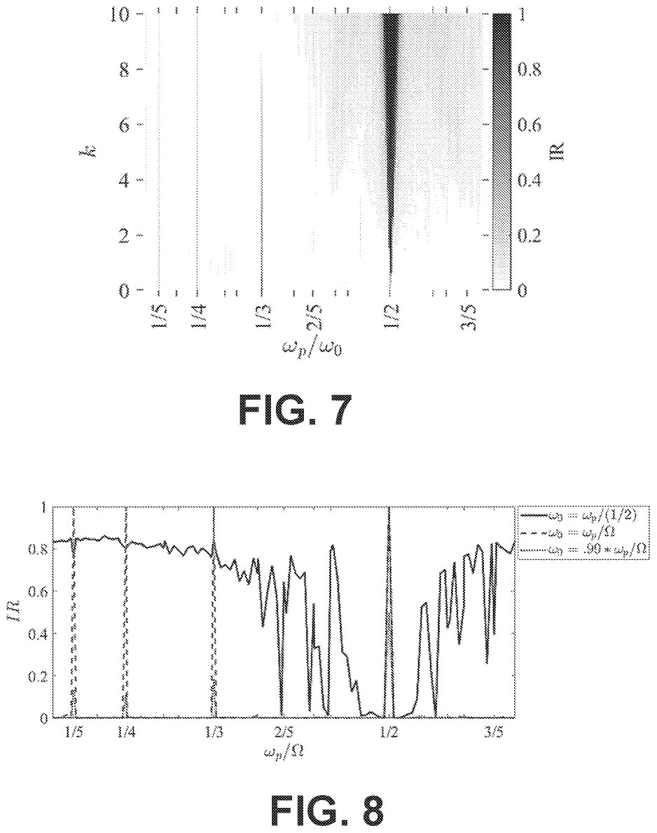

By focusing on a set forcing frequency, Ω, a computational Arnold tongue may be seen. FIG. 7 illustrates this behavior. Using an XOR task as a benchmark of the Hopf physical reservoir computer, a computational Arnold tongue is shown at

$$\frac{{ω}_{p}}{ω} = \frac{1}{2} .$$

This computational Arnold tongue tapers down as k decreases. Thus, a small mistuning of the resonance value will require a larger amount of power as compensation. Here, μ=3, ωₚ=20π, and Ω=40π. As mentioned above, the Hopf physical reservoir computer is highly susceptible to mistuning of the static ω₀ term. The computational Arnold tongue suggests that this may be partially compensated by increasing the gain. However, this comes at the price of increasing the energy expenditure required by the Hopf physical reservoir computer.

Next, the behavior of three different cases for ω₀ are interrogated in FIG. 8 (μ=5, k=5, and ωₚ=20π). Using an XOR task as a benchmark, the effects of the static resonance, ω₀, on the computational ability of the Hopf physical reservoir computer are shown. When

$${ω}_{0} = \frac{{ω}_{p}}{1 / 2} ,$$

the Hopf physical reservoir computer has nominal performance for many values of

$$\frac{{ω}_{p}}{Ω} ,$$

although the only good performance coincides with

$$\frac{{ω}_{p}}{Ω} = \frac{1}{2} .$$

### When

$${ω}_{0} = \frac{{ω}_{p}}{Ω} ,$$

good performance coincides with several Farey sequence ratios, as expected from the results in FIG. 6. However, a very small mistuning (here, 1%) can cause a drastic degradation of the performance

$$( e . g . , when {ω}_{0} = 0.99 \frac{{ω}_{p}}{Ω} ) .$$

This points to the necessity of a dual learning approach, in which an adaptive oscillator can be used to enhance the physical reservoir computer's performance by learning the correct resonance.

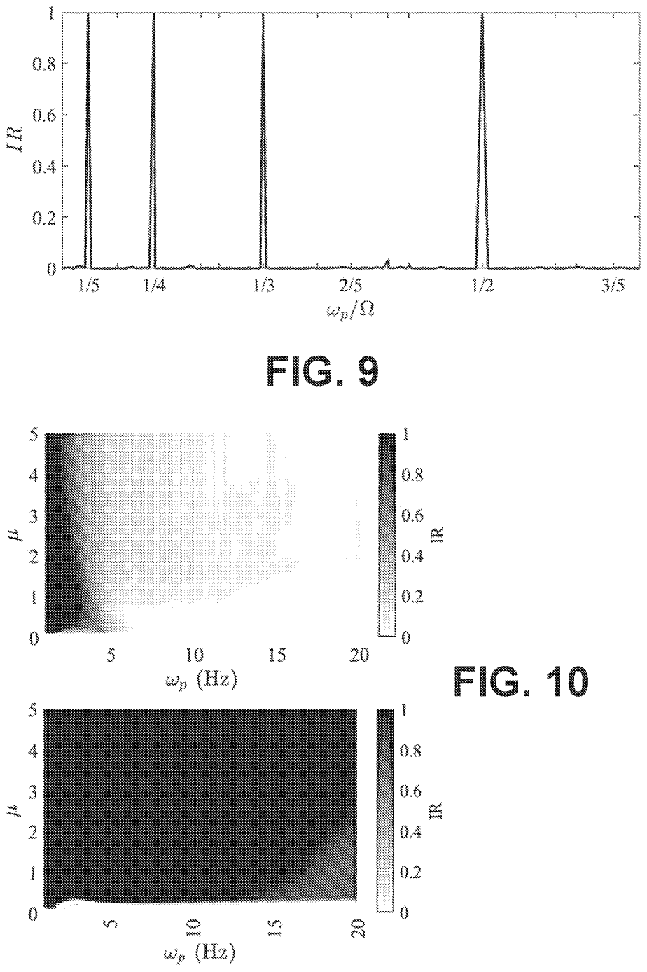

The behavior of the adaptive oscillator physical reservoir computer is shown in FIG. 9 (μ=5, k=5, and ωₚ=20π). Using an XOR task as a benchmark, the effect of the dynamic resonance, ω, on the computational ability of the adaptive oscillator physical reservoir computer is shown. This behavior can be directly compared with the behavior of the Hopf physical reservoir computer, which is shown in FIG. 8. The initial condition for the w state of the adaptive oscillator was set to

$$0.95 \frac{{ω}_{p}}{Ω} ,$$

which is a 5% error for the starting value of ω. However, unlike the case of 1% error shown in FIG. 8, the adaptive oscillator learns the correct frequency, and the physical reservoir computer's response is quite similar to the case in which

$${ω}_{0} = \frac{{ω}_{p}}{Ω}$$

for the Hopf physical reservoir computer. This points to the practical advantage of leveraging adaptation to provide robustness to physical reservoir computing.

To highlight the adaptive oscillator physical reservoir computer's dual learning ability, it was compared with the Hopf physical reservoir computer in FIG. 10. Using an XOR task as a benchmark, the effect of dynamic learning of the adaptive oscillator physical reservoir computer is highlighted. To show this, the pseudo-frequency, cop, was varied, and the forcing frequency was set as Ω=2ωₚ to match the resonance condition shown in previous figures (e.g., FIG. 9). The initial condition for the ω state of the adaptive oscillator and the static resonance parameter, ω₀, of the Hopf oscillator were both set to 0.95Ω. As shown on the left, the Hopf physical reservoir computer only works for small values of ωₚ, while the adaptive oscillator physical reservoir computer works for a wide range of frequencies. Here, k=5 and Ω=2ωₚ; additionally, a portion of time was simulated that was not used in the training with k=25 to allow the ω state to learn.

For this comparison, the pseudo-frequency was varied over an arbitrary range of frequencies, and D was set equal to 2ωₚ to match the resonance condition shown in FIG. 9. As indicated, both ω₀ (for the Hopf oscillator) and ω (for the adaptive oscillator) were both set equal to 0.95Ω, which is a 5% error from a resonance condition. The Hopf oscillator has a narrow region of good performance; this may be attributed to the percentage difference for these small frequencies also being small. The adaptive oscillator, on the other hand, is able to learn the correct resonance condition. This dual learning allows the adaptive oscillator physical reservoir computer to function effectively.

### Field-Programmable Analog Array Experiment

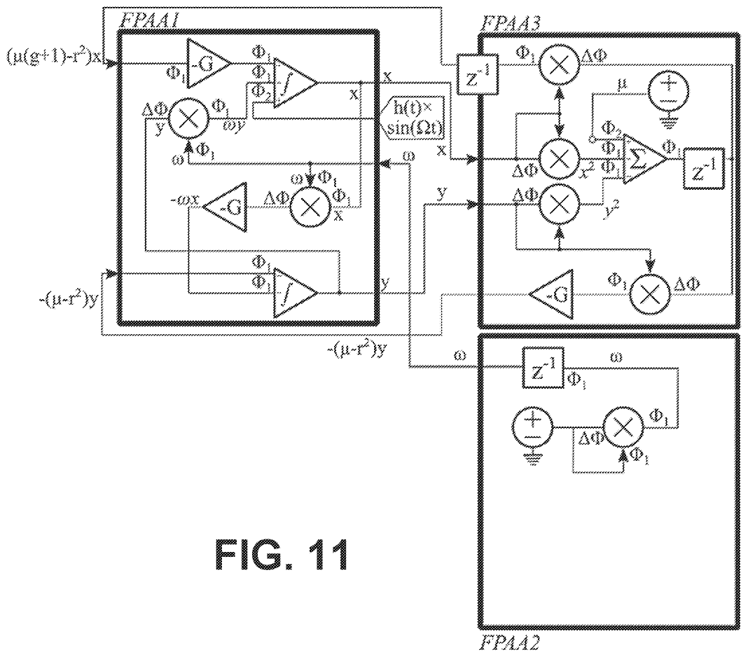

An analog circuit was constructed on a field-programmable analog array (FPAA) to experimentally validate the adaptive oscillator physical reservoir computer. FPAAs are the analog counterpart to field-programmable gate arrays, and they use a switched-capacitor technology. FPAAs are highly reconfigurable, which makes them ideal for prototyping analog circuits. They have been used for the Lorenz system, neuron models, and chaotic oscillators. An FPAA implementation of a four-state adaptive oscillator has also been constructed. FIG. 11 shows a circuit schematic for the adaptive oscillator physical reservoir computer. Three FPAA AN231 E04 chips (Anadigm, Paso Robles, CA) were used, which are designated as “FPAA1”, “FPAA2”, and “FPAA3”. The external forcing function, f(t) and g(t), are sent to the FPAA from MATLAB via a National Instruments 9263 module.

In the circuit shown in FIG. 11, the limit cycle's radius is r=\sqrt{x²+y²}. The circuit used three of the four AN231 E04 chips on an Anadigm QuadApex board. The external signal, f(t) and g(t), was generated in MATLAB and sent to FPAA2 via a National Instruments 9263 module. The x, y, and ω states were collected back to MATLAB via a National Instruments 9201 module. In this circuit, several configurable analog modules (CAMs) were used. These included summation, multiplication, integration, sample-and-hold (represented by Z⁻¹), and DC voltage CAMs (represented by a circle with a ±symbol inside).

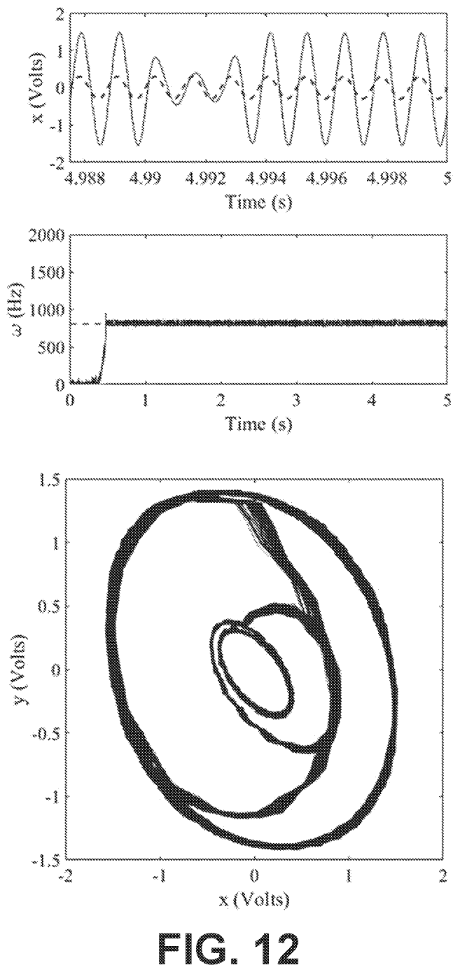

An example of a response of the adaptive oscillator physical reservoir computer is shown in FIG. 12. For the XOR task, the circuit performed with a modified information rate of 0.99. The response for this set of parameters is representative over the operational range of the circuit. On the top of FIG. 12, a portion of the time history is shown. The sinusoidal forcing, f(t), is represented by a dashed line for reference, and the x state is plotted in a solid line. The x state is nearly entrained to the external force. On the middle of FIG. 12, the ω state is plotted. The Ω value is represented by a dashed line for reference, and the ω state is plotted in a solid line. After a learning period, the adaptive oscillator learns the forcing frequency. On the bottom of FIG. 12, the phase space is plotted, which has a rather complicated form. For this example, the information rate was calculated to be 0.99. For this experiment, μ=3, a=0.3, k=0.333, N=20, ωₚ=400 Hz, and Ω=800 Hz.

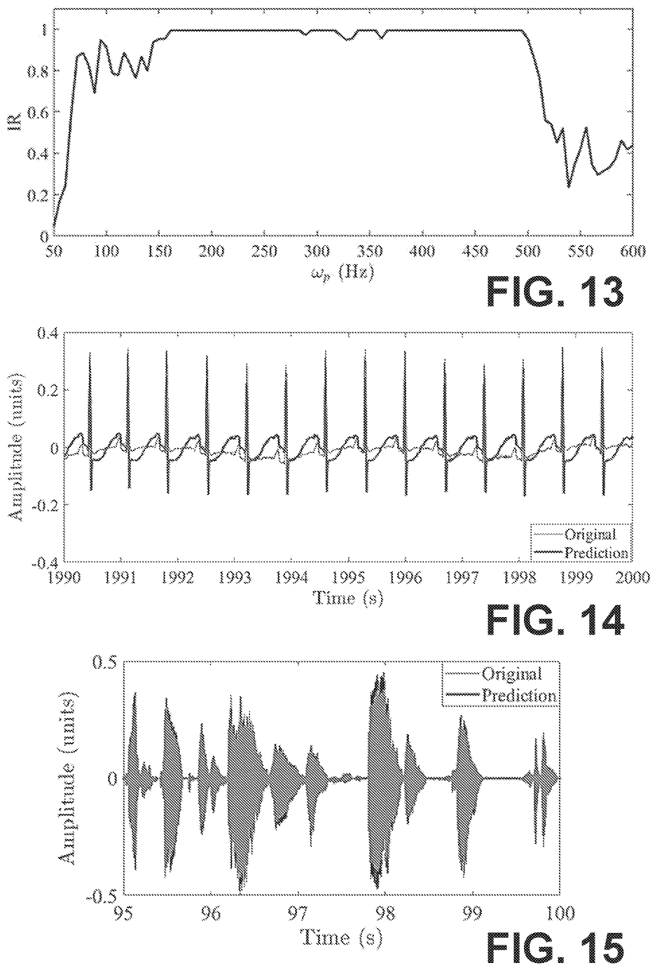

FIG. 13 illustrates an example of the operational range of the FPAA circuit is shown here. The operational range of the FPAA circuit is explored for a set of parameter values. Here, μ=3, a=0.2, k=0.5, N=20, and

$$Ω = \frac{{ω}_{p}}{1 / 2} .$$

As physical circuits have limiting constraints that are not present in the idealized model, the physical circuit has a reduced operational range. It should be noted that this operational range can be optimized by modifying the circuit parameters. The FPAA circuit has near ideal performance over the range from approximately 150 Hz to 500 Hz. The operational range can be optimized for different configurations. For example, the operational range can be increased by optimizing the circuit design and implementing it as a printed circuit board. This provides both robustness to mistuned frequencies of the oscillator, and it also provides a reconfigurable sampling rate for different use cases. Moreover, the response of the physical reservoir computer has degraded performance outside this region, as compared to the steep drop in performance for the Hopf physical reservoir computer. In real-world scenarios, this would provide a further degree of robustness.

### Self-Learning Physical Reservoir Computer

A self-learning physical reservoir computer is demonstrated as an adaptive oscillator. Whereas physical reservoir computing repurposes the dynamics of a physical system for computation through machine learning, adaptive oscillators can innately learn and store information in plastic dynamic states. The adaptive state(s) can be used directly as physical node(s), but these plastic states can also be used to self-learn the optimal reservoir parameters for more complex tasks utilizing virtual nodes from the base oscillator. Both this self-learning property for reconfigurable computing and the morphable logic gate property of the adaptive oscillator make this an ideal candidate for a multi-purpose neuromorphic processor.

A new architecture of a PRC is presented, which uses an adaptive oscillator (AO) as the reservoir. Notably, the AO itself is a neuromorphic computer that only uses dynamics for memory storage and learning. The PRC comprising an AO exhibits self-learning, which increases its own power as a PRC without any programming. The methodology presented here uses the AO's intrinsic dynamic learning to optimize the PRC's computational ability. Further, this AO PRC has no synapses, so the oscillator's adaptive states are the only source of plasticity for this system, and only one of the oscillator's states is used for creating virtual nodes. This form of self-learning provides enhanced robustness and reconfigurability. Specifically, this reservoir-level self-learning unlocks the potential of the PRC to be used for applications with a wide range of frequencies and sampling rates. Examples of the PRC's self-learning property are highlighted using low frequency and high frequency applications (e.g., heart analysis and audio recognition tasks).

The equations of motion for the AO considered here are:

$$\dot{x} = ( μ f ( t ) - ( {x}^{2} + {y}^{2} ) ) x - ω y + af ( t )$$

$$\dot{y} = ( μ f ( t ) - ( {x}^{2} + {y}^{2} ) ) y + ω x$$

$$\dot{ω} = - kf ( t ) y$$

where f(t) is a continuous function, which is constructed from a discrete function, h(z), and a sinusoid. First, [symbol] is a continuous function, which is equal to a value of h for a length of time equal to the pseudo-period, T_{P}. T_{P} is an arbitrary length of time, which is used to also define a pseudo-period as

$${ω}_{P} = \frac{2 π}{{T}_{P}} .$$

The continuous function, g(t), is defined as:

$$g ( t ) = h ( {z}_{n} ) for {nT}_{P} \leq t < ( n + 1 ) {T}_{P}$$

This g(t) function encodes information from various data sources. The external force, which is applied to the oscillator, is defined as f(t)=g(t)*sin (Ωt).

Various benchmarking tasks were carried out for comparison. FIG. 14 shows an example of the AO PRC performing a one-step-ahead heart ECG signal prediction task. The RMSE for the test portion of this task was 0.00086, while the RMSE of the baseline (assuming a prediction equal to the average value of the signal) was 0.02104. FIG. 15 shows an example of the AO PRC performing a one-step-ahead speech prediction task. The RMSE for the test portion of this task was 0.00966, while the RMSE of the baseline (assuming a prediction equal to the average value of the signal) was 0.05838.

Using an XOR task as a benchmark of the Hopf PRC, a computational Arnold tongue is shown at

$$\frac{{ω}_{P}}{ω} = \frac{1}{2}$$

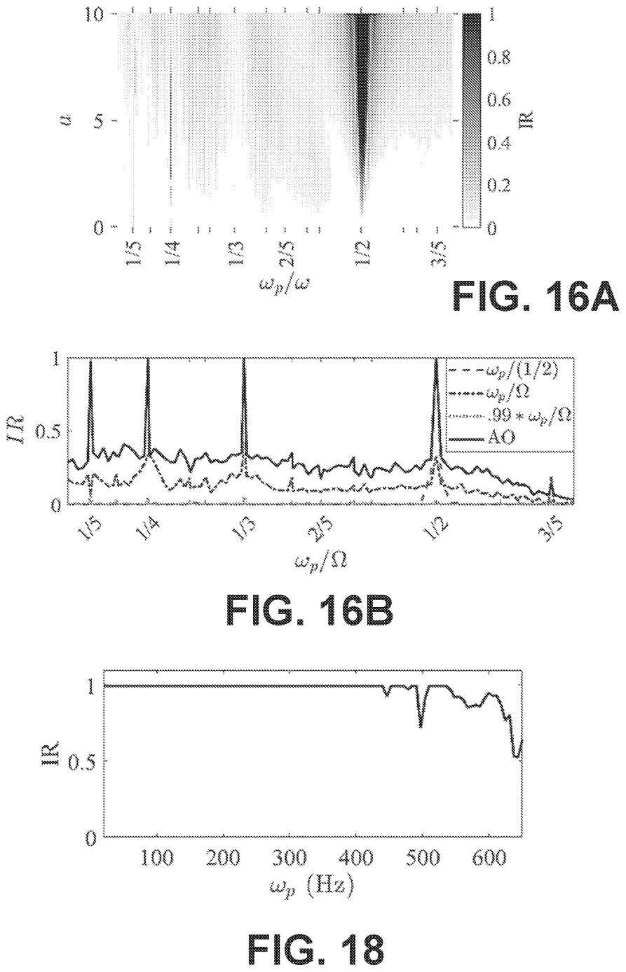

in FIG. 16A. This computational Arnold tongue tapers down as α decreases. Thus, a small mistuning of the resonance value will require a larger amount of power as compensation. In FIG. 16B, the effects of the static resonance, ω₀, on the computational ability of the Hopf PRC (dashed or dotted lines) are compared to the dynamic resonance, ω, of the Hopf AO PRC (solid line). However, the AO learns the correct frequency, so it has high performance at several Farey sequence numbers, as compared to the performance of the Hopf PRC.

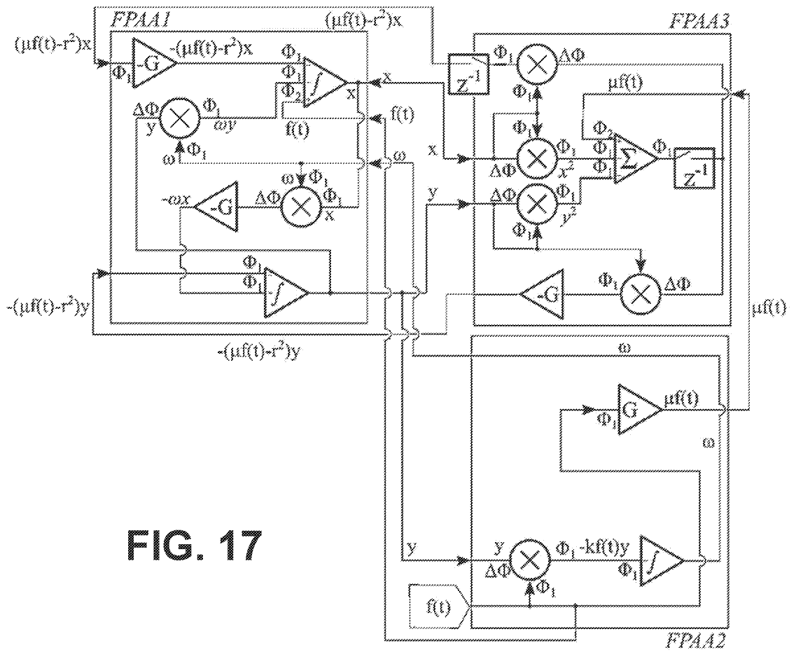

FIG. 17 shows a circuit schematic for the OA physical reservoir computer. The experimental field-programmable analog array circuit is shown here. Three FPAA AN231 E04 chips (Anadigm, Paso Robles, CA) were used, which are designated as “FPAA1”, “FPAA2”, and “FPAA3”. The external forcing function, f(t), was sent to the FPAA from MATLAB via a National Instruments 9263 module. The operational range of the FPAA circuit is shown in FIG. 18. As physical circuits have limiting constraints that are not present in the idealized model, the physical circuit has a reduced operational range. The FPAA circuit has near ideal performance over the range from approximately 20 Hz to 490 Hz.

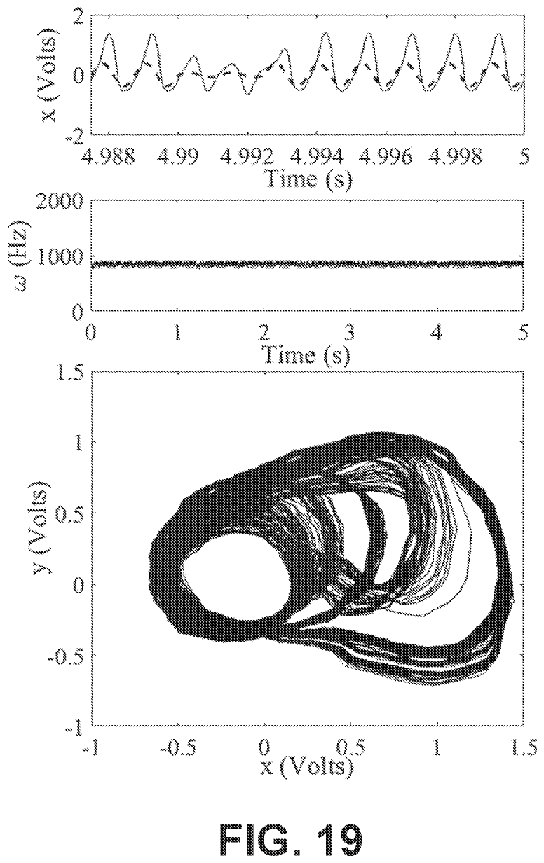

FIG. 19 illustrates an example of the response of the FPAA circuit. On the top, a portion of the time history of x (solid line) is plotted with f(t) (dashed line). In the middle, the ω state (solid line) is plotted with the Ω value (dashed line) for reference. On the bottom, the phase space is plotted. For this example, the information rate was calculated to be 0.99 (e.g., perfect reconstruction).

Adaptive Oscillator Physical Reservoir Computer without Time Multiplexing

In addition to the methods described above, the adaptive oscillator can be used as a physical reservoir computer without the need of cumbersome time multiplexing (e.g., no virtual nodes are needed). In this case, the equations of motion for the four-state adaptive oscillator are used as an example:

$$\dot{x} = ( μ - ( {x}^{2} + {y}^{2} ) ) x - ω y + {k}_{x} ( f ( t ) - x α ) \qquad ( 9 )$$

$$\dot{y} = ( μ - ( {x}^{2} + {y}^{2} ) ) y + ω x$$

$$\dot{ω} = - {k}_{ω} ( f ( t ) - x α ) y$$

$$\dot{α} = {k}_{α} ( f ( t ) - x α ) x$$

When this adaptive oscillator is forced with a single sinusoid, such as a sin(Ωt), the ω state will converge to Ω and the α state will converge to a, kₓ, k_{ω}, and k_{α} are constants that affect the learning rate of the adaptive oscillator. In eq. (9), f(t) is a time-varying external force, which encodes information that is sent to the adaptive oscillator. For the logic tasks considered here, “True” is encoded as Ω_{TRUE} and “False” is encoded as Ω_{FALSE}, and the external forcing function is defined as:

$$f ( t ) = \frac{1}{2} sin ( {Ω}_{i} t ) + \frac{1}{2} sin ( {Ω}_{j} t ) \qquad ( 10 )$$

The “True” or “False” values are chosen at random with equal probability, which are then encoded as Ω_{I} and Ω_{J}. These frequency values are held constant for a pseudo-period, T_{P}, that is significantly longer than the period of Ω_{TRUE} and Ω_{FALSE}. This pseudo-period can be considered as the clock frequency, such that a logic gate can be calculated once for each pseudo-period. As no time multiplexing is used, the nodes for each clock are simply a bias value (e.g., 1), the ω state value, and the α state value. The ω and α values are taken just before the next clock cycle to allow the adaptive oscillator to reach a steady state response. Thus, the nodes are [1, ω(nT_{P}−δ), α(nT_{P}−δ)], where nϵ [symbol] and δ>0 is an arbitrarily small constant.

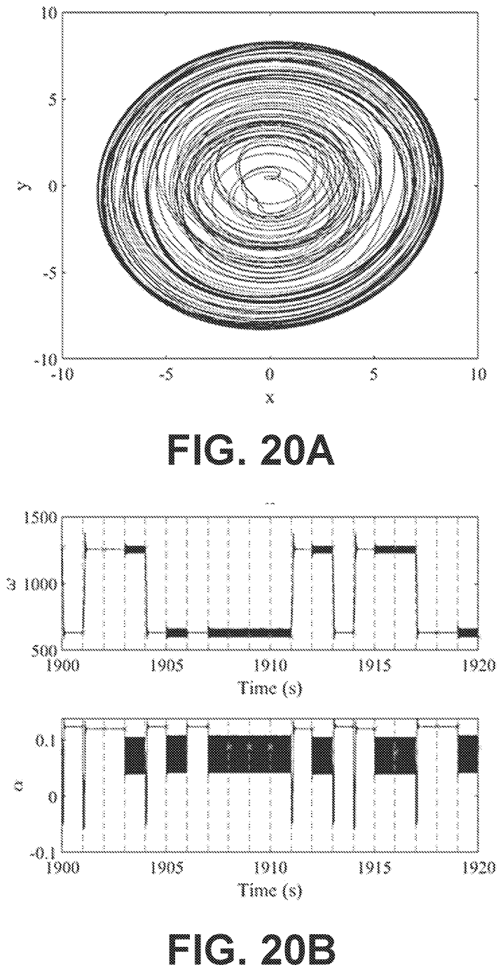

An example of the time history of the adaptive oscillator PRC is shown in FIGS. 20A and 20B. The phase portrait of the x and y states are shown in FIG. 20A. A portion of the response of the ω state (top) and the α state (bottom) are plotted in FIG. 20B for reference. The vertical dashed lines correspond to the start of a clock cycle (e.g., these vertical lines delineate the pseudo-periods), and the “X” symbols are the nodal value components. Here, Ω_{FALSE}=200π, Ω_{TRUE}=400π, T_{P}=1, μ=1, kₓ=1000, k_{ω}=10000, and k_{α}=10.

### Logic Gates

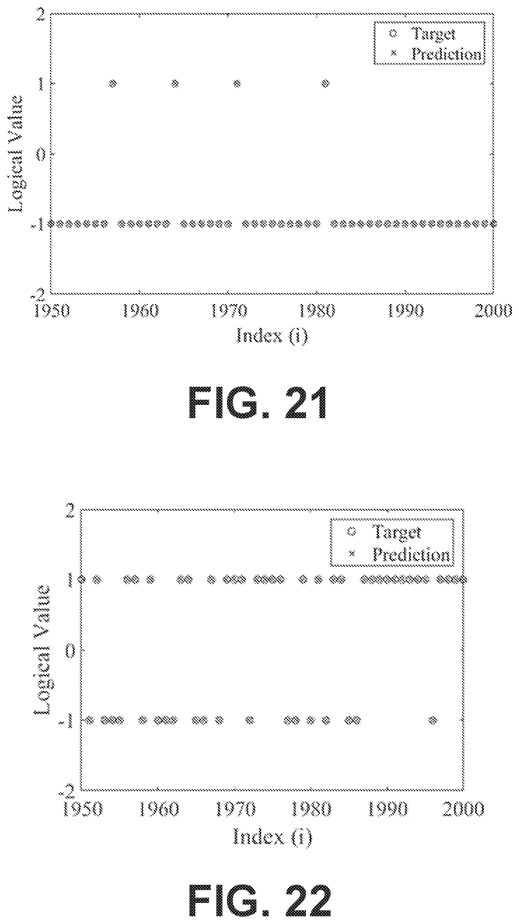

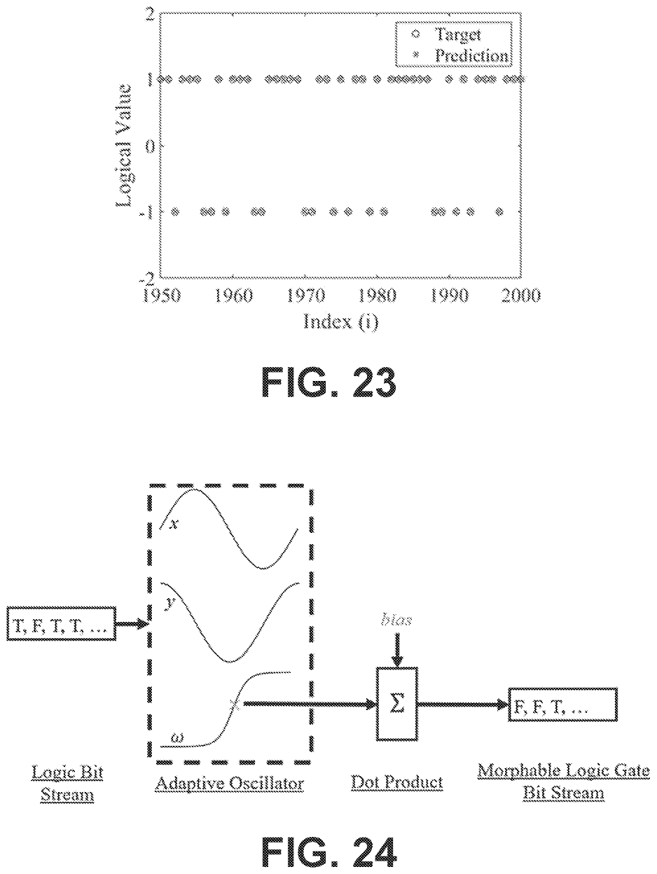

To highlight the efficacy of this physical reservoir computer, the NOT, AND, and OR gates are demonstrated, without modifying the adaptive oscillator itself. Thus, the reprogrammability of this system is solely based on the machine learning that is applied to the nodal outputs. The AND gate operation is shown in FIG. 21, the OR gate operation is shown in FIG. 22 and the NOT gate operation is shown FIG. 23.

FIG. 21 illustrates an example of the adaptive oscillator acting as an AND (∧) gate. For the AND task, H(x)=0.73, and IR=0.73. Thus, the adaptive oscillator PRC works as an AND gate. FIG. 22 illustrates an example of the adaptive oscillator acting as a OR (∨) gate. For the OR task, H(x)=0.86, and IR=0.86. Thus, the adaptive oscillator PRC works as an OR gate. FIG. 23 illustrates an example of the adaptive oscillator acting as a NOT (¬) gate. For the NOT task, H(x)=1.0, and IR=1.0. Thus, the adaptive oscillator PRC works as a NOT gate. In all cases, Ω_{FALSE}=200π, Ω_{TRUE}=400π, T_{P}=1, μ=1, kₓ=1000, k_{ω}=10000, and k_{α}=10. For the NOT task, the external force was modified as f(t)=sin(Ωᵢt), since the NOT gate takes a single value. For each of these logic gates, the modified information rate was at a maximal value (e.g., the IR was equal to H(x)). Thus, the adaptive oscillator physical reservoir computer can act as the basic logic gates, without multiplexing and without being tuned. Previous types of dynamic computing required tuning the nonlinear system to correspond to different logic gates.

### Multiplex-Free Morphable Logic Gates Using an Adaptive Oscillator Physical Reservoir Computer

A Hopf adaptive oscillator with an adaptive frequency state can be employed as a PRC for time-multiplexing free, morphable logic gates. The AO PRC's equations can be written as:

$$\dot{x} = ( μ - ( {x}^{2} + {y}^{2} ) ) x - ω y + af ( t )$$

$$\dot{y} = ( μ - ( {x}^{2} + {y}^{2} ) ) y + ω x$$

$$\dot{ω} = - kf ( t ) y$$

Bits, which are encoded as sinusoids, are sent to the adaptive oscillator sequentially. It should be noted that the adaptive oscillator effectively “remembers” a previous value to operate on the current value for binary operations, such as the AND and/or OR tasks.

Nonphysical reservoir computers are constructed from recurrent neural networks with some hidden layers (i.e., the reservoir) that have random, untrained weights. The output of the reservoir can be trained with a simple method, such as a ridge regression. A physical reservoir computer (PRC) effectively replaces the software recurrent neural network with a physical system. Another way, input information can be sent to a physical system as external force(s), the physical reservoir transforms and stores this information as a dynamic response, and the dynamic response is trained (e.g., with ridge regression) to produce a desired output. A schematic of this process for the adaptive oscillator is shown in FIG. 24.

FIG. 24 schematically illustrates the adaptive oscillator physical reservoir computer considered here. A logic bit stream is sent to the adaptive oscillator, and only a single node is collected from the ω state for each clock cycle. Thus, the adaptive oscillator “remembers” the previous bit to perform the logic gate correctly. The Σ denotes the readout layer, which takes a dot product of the weights from the ridge regression with the node and bias. The value of the dot product produces a morphable logic gate bit stream.

In physical reservoir computing, the dynamic response of a nonlinear system is used as a computational resource by applying machine learning techniques. Reservoir computing came from liquid state machines and echo state networks. Since PRCs do not have static information storage, they are different from Turing machines. Many different time-dependent systems have been explored as physical reservoir computers. These include the Hopf oscillator, van der Pol oscillator, memristors, a Duffing array, quantum reservoir networks, superparamagnetic tunnel junctions, an array of linear oscillators, spintronics, lasers in special mediums, microelectromechanical systems, a shape memory alloy actuator, and the nonlinear response of materials.

On the other hand, adaptive oscillators are a subset of nonlinear oscillators that can learn and store information in dynamic plastic states. For instance, the Hopf adaptive frequency oscillator has two states that correspond to the nonadaptive Hopf oscillator, while the remaining state can learn and store an external forcing frequency. This can be extended to include states for amplitude or more complex waveforms. Since linear vibratory energy harvesters employ resonance to boost performance and nonlinear harvesters use nonlinearity to increase bandwidth, adaptive oscillators may be ideal vibratory energy harvesters since they can track resonance (e.g., the pendulum adaptive frequency oscillator). Interestingly, adaptive oscillators can also exhibit chaotic motion for certain parameter combinations.

Oscillator-based physical reservoir computers typically employ time multiplexing to create virtual nodes. For vibrating systems, this is a seemingly necessary step to capture the needed information from the system, as computing and memory storage are both provided by the oscillator itself. This is cumbersome from a practical perspective, as it requires a faster sampling rate than the clock frequency. For time multiplexing, a piece of information (e.g., a logic bit, a single sample from an audio recording, or a pixel, etc.) is sent to the oscillator, and the oscillator's response is sampled n times. These n samples of the oscillator are considered to be virtual nodes, as they are sampled in time from a single state of the oscillator. Conversely, a sensor array may instead be sampled when the array is subjected to a force; thus, for spatial multiplexing, the nodes are physical. Effectively, both time and spatial multiplexing are employed to project a single piece of data to a vector in a larger space. For a physical reservoir computer composed of an adaptive oscillator, time multiplexing can be completely avoided. As only a single node is collected for each pseudoperiod, the nodes considered in this disclosure are physical nodes, even though it is an oscillator. The adaptive oscillator's response at a single instance per clock cycle directly provides the calculation of different logic gates. Interestingly, this approach creates a reprogrammable logic gate, without the necessity of modifying the adaptive oscillator itself.

In comparison, nonlinear oscillators can also be used for reprogrammable logic gates, in which the dynamics of the oscillator are modified to correspond as different gates. For instance, a bistable oscillator's asymmetry can be tuned to produce different logic gates, lattices of coupled chaotic maps set a critical value to function as different gates, and a Duffing oscillator can be used as a reprogrammable logic gate by incorporating a feedback controller. Here, the disclosed adaptive oscillator PRC utilizes the complex dynamic response of the oscillator to avoid modifying the oscillator itself (i.e., no feedback or parameter tuning is necessary). At the same time, machine learning is used to reprogram the nonmultiplexed response to correspond to different logic gates using a single sample per clock cycle. Since this is done without modifying the base oscillator's parameters, all of the logic gates can be simultaneously calculated in parallel by the physical reservoir computer.

### Adaptive Oscillator Physical Reservoir Computer

The adaptive oscillator considered in this paper is based on the Hopf oscillator, whose equations of motion are given in eq. (1). Here, p is a parameter that affects the limit cycle radius, and ω₀ is the static resonance frequency of the Hopf oscillator. It should be noted that other adaptive oscillators can be constructed with different base oscillators, and these other adaptive oscillators should exhibit a similar performance as physical reservoir computers. By concatenating an additional state onto eq. (1), the Hopf-based adaptive oscillator is constructed that can learn and store frequency information as given by eq. (2), where k(f(t))=kₓf(t) and −k(f(t))y=−k_{ω}f(t)y. In some cases, kₓ=k_{ω}, while in other cases, the k value in the \dot{x} equation is different than the k value in the \dot{ω} equation, in which case kₓ≠k_{ω}.

When this adaptive oscillator is forced with a single sinusoid, such as a sin(Ωt), the ω state will converge to Ω, kₓ and k_{ω} are constants that affect the learning rate of the adaptive oscillator. In eq. (2), f(t) is a time-varying external force, which encodes information that is sent to the adaptive oscillator. For the logic tasks considered here, “True” is encoded as Ω_{TRUE} and “False” is encoded as Ω_{FALSE}, and the external forcing function is defined simply as f(t)=sin(Ωᵢt).

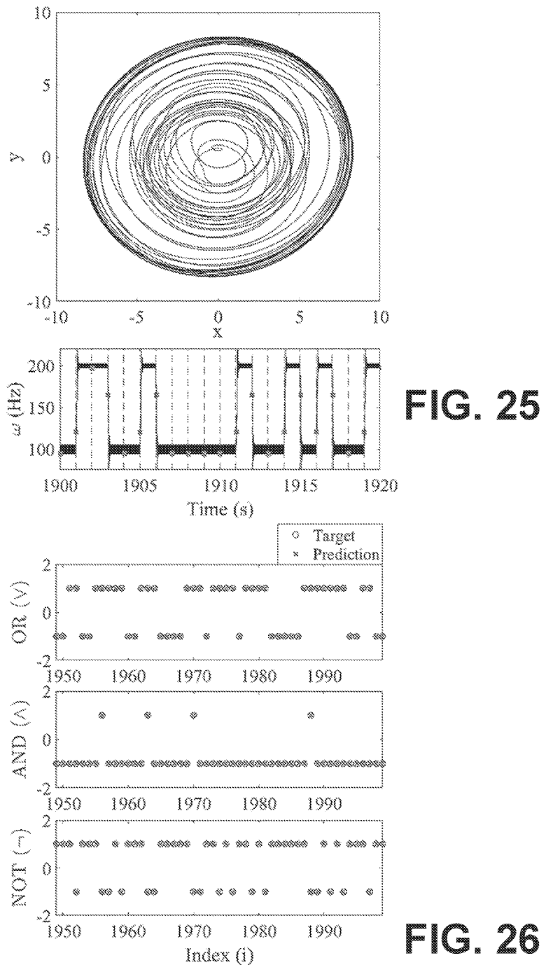

The “True” or “False” values are chosen at random with equal probability, which are then encoded as Ωᵢ. This frequency value is held constant for a pseudoperiod Tₚ that is significantly longer than the period of Ω_{TRUE} and Ω_{FALSE}. The pseudoperiod can be considered as the clock frequency, such that a logic gate is calculated once for each pseudoperiod. As no time multiplexing is used, the nodes for each clock are simply a bias value (e.g., 1) and the ω state value. The ω values are taken just after each clock cycle to capture the adaptive oscillator in a transient state. Thus, the nodes are [1, ω(nTₚ+δ)], where nϵ [symbol] and δ is a small constant. An example of the time history of the adaptive oscillator PRC is shown in FIG. 25.

FIG. 25 shows the phase portrait of the x and y states on the top. A portion of the response of the ω state is plotted for reference on the bottom. The dashed lines correspond to the start of a clock cycle (e.g., these vertical lines delineate the pseudoperiods), and the x's are the nodal value components. In FIG. 25, Ω_{FALSE}=100 Hz, Ω_{TRUE}=200 Hz, Tₚ=1, μ=1, kₓ=1000, k_{ω}=10 000, δ=0.02 s. Bits, which are encoded as sinusoids, are sent to the adaptive oscillator sequentially. It should be noted that the adaptive oscillator effectively “remembers” a previous value to operate on the current value for binary operations, such as the AND and/or OR tasks.

### Modified Information Rate

A modified version of Shannon's information rate is a relevant metric for logic gates, as the root-mean-square error is poorly defined for these logical tasks. The modified version is defined in terms of the original information rate, where the “sent” and “received” signals are replaced with the correct and predicted output of the gate, respectively.

The Shannon entropy H(x) is the amount of information in the output. It should be noted that bits being sent to the logic gates are randomly chosen as “True” or “False” values with equal probability, but some of the gates do not have an equal probability of being “True” or “False.” For instance, the NOT gate preserves the equal probability distribution, but the AND gate is “True” only 25% of the time (e.g., when both inputs are “True”). This unequal probability affects the upper limit on the information rate for different gates. For a bit i from the target of the gate and a bit j from the prediction of the gate, the Shannon entropy is defined as in eq. (7), where the conditional probability is given by eq. (6).

The conditional entropy H_{y}(x) is the probability of an incorrect calculation of the gate. The conditional entropy is defined in terms of a joint probability p(i,j) as in eq. (8). Thus, the modified Shannon's information rate is calculated as given by eq. (5). If the adaptive oscillator PRC functions correctly as a logic gate, the IR value of the target will be equal to the H(x) value of the prediction.

### Logic Gates

To highlight the efficacy of this physical reservoir computer, the NOT, AND, and OR gates are demonstrated, without modifying the adaptive oscillator itself. Thus, the reprogrammability of this system is solely based on the machine learning that is applied to the nodal outputs.

FIG. 26 illustrates examples of the adaptive oscillator acting as an AND (∧), OR (∨), and NOT ( [symbol] ) gate. For each task, the H(x) and information rate (IR) values were equal, which demonstrates that they work correctly [OR: H(x)=0.81, IR=0.81; AND: H(x)=0.74, IR=0.74; NOT: H(x)=1.0, IR=1.0]. In FIG. 26, Ω_{FALSE}=100 Hz, Ω_{TRUE}=200 Hz, Tₚ=1, μ=1, kₓ=1000, k_{ω}=10 000, δ=0.02 s. Since the bits are sent to the adaptive oscillator sequentially, the system must effectively “remember” one bit to calculate the OR and AND tasks. The transient behavior of the adaptive oscillator's W state provides a simple and effective method for collecting nodes from the system, without relying on time multiplexing.

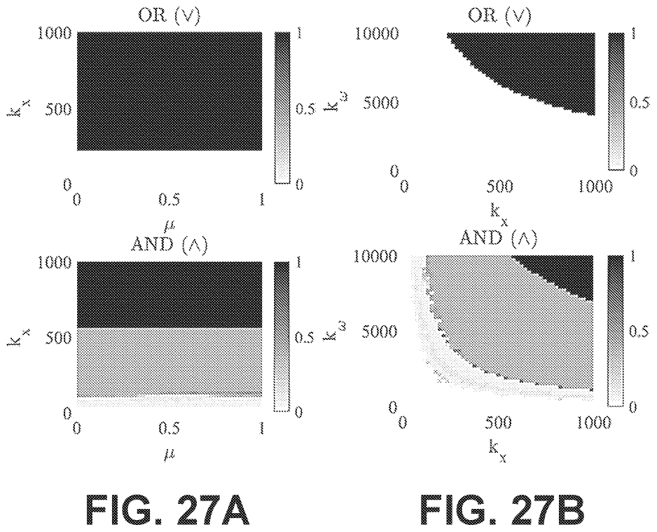

In FIGS. 27A and 27B, the relationship between the computational system parameters are explored. As the Hopf oscillator is a nonlinear system, the computational ability is highly reliant on the oscillator's parameters, as can be seen in the bifurcated response in these figures. The normalized information rate

$$[ \frac{IR}{H ( x )} ]$$

(shown as the color axis in FIGS. 27A and 27B) is used to quantify the computational ability for the AND (∧) and OR (∨), which both require the oscillator to remember the previous bit. FIG. 27A explores the relationship between the μ term and the kₓ term for the AND (∧) and OR (∨) gates. In FIG. 27A, Ω_{FALSE}=100 Hz, Ω_{TRUE}=200 Hz, Tₚ=1, k_{ω}=10 000, δ=0.02 s. FIG. 27B explores the relationship between the kₓ term and the k_{ω} term for the AND (∧) and OR (∨) gates. In FIG. 27B, Ω_{FALSE}=100 Hz, Ω_{TRUE}=200 Hz, Tₚ=1, μ=1, δ=0.02 s.

In FIG. 27A, there is a rather quantized relationship between kₓ and the computational ability, whereas the μ term has little effect on the computational ability. For the OR gate, there are only two quantized levels, whereas there are approximately three quantized levels of computational ability for the AND gate. A relatively large value of kₓ (above approximately 560) results in both gates working correctly. In FIG. 27B, both the kₓ and k_{ω} terms affect the computational ability of the AO PRC. For the OR gate, there are still only two quantized levels. The AND gate has a more graded response before having a quantized jump to perfect computing. A combination of parameters, such as (kₓ=1000, k_{ω}=10 000), results in perfect computation for both gates.

### FPAA Circuit

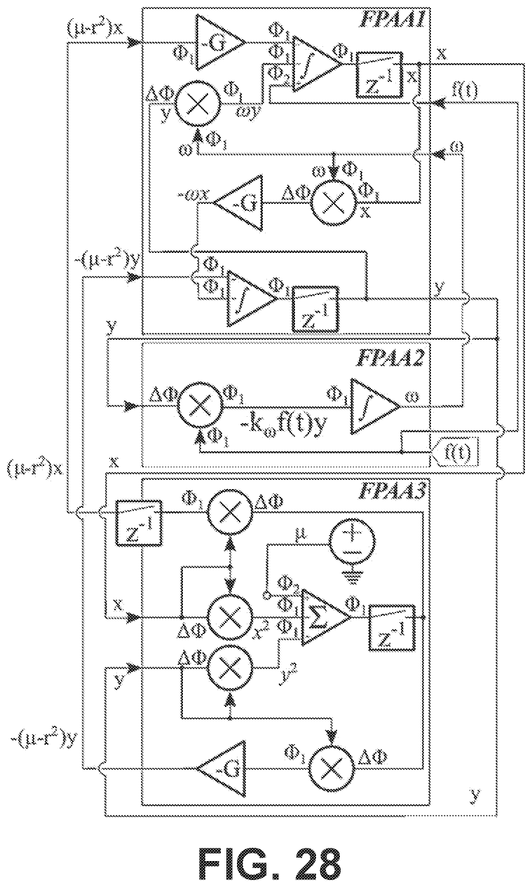

A field-programmable analog array (FPAA) experiment is used to validate the performance of the adaptive oscillator PRC. FPAAs, which use switched-capacitor technology, are highly reconfigurable analog circuits. Many different nonlinear oscillators have been constructed with FPAAs, such as the van der Pol oscillator, Lorenz system, four-state adaptive oscillator, and a chaotic adaptive pendulum. The adaptive oscillator PRC's circuit schematic is shown in FIG. 28. Three FPAA AN231 E04 chips on an Anadigm QuadApex board (Anadigm, Paso Robles, CA) were used.

The external signal f(t) was generated in MATLAB. Next, it was sent to FPAA2 using a National Instruments 9263 module. A National Instruments 9201 module was used to collect the x, y, and ω states. Several configurable analog modules (CAMs) were used, including summation, multiplication, integration, dc voltage, and sample and hold. The r term denotes the limit cycle's radius, which is r=\sqrt{x²+y²}.

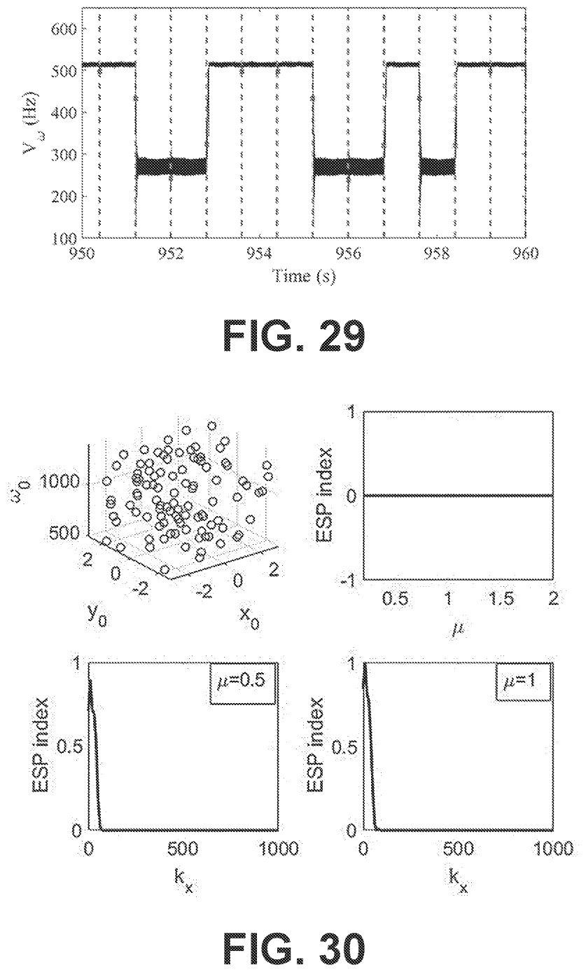

FIG. 29 illustrates a portion of the ω state from the FPAA experiment. The dashed lines correspond to the clock, and the Xs correspond to the nodes that are sampled during the transient portion of the dynamics after each clock cycle. In FIG. 29, Ω_{FALSE}=250 Hz, Ω_{TRUE}=500 Hz, Tₚ=0.8, μ=2, kₓ=0.375, k_{ω}=0.125, δ=0.004 s. As with the experiment, the adaptive oscillator PRC functions perform the OR, AND, and NOT tasks correctly, with the same calculated results as shown in FIG. 26. As with the simulation results, the nodes are [1, ω(nTₚ+δ)]. The same regression procedure was used to train the PRC to reproduce the three considered logic gates.

### Echo State Property

The echo state property (ESP) is often considered to be a necessary condition for a system to work properly as a PRC. Here, the ESP index was calculated to determine if the AO PRC has the echo state property, which is shown in FIG. 30. The top left plot shows the set of random initial conditions for the ESP index calculations. The top right plot shows the ESP index for the AO PRC for kₓ=1000 and k_{ω}=10 000. The bottom left plot shows the ESP index for the AO PRC for μ=0.5 and k_{ω}=10 000. The bottom right plot shows the ESP index for the AO PRC for μ=1 and k_{ω}=10 000. A PRC possesses the echo state property if the response of the reservoir is independent of the initial conditions. Thus, a PRC has the echo state property if the effect of the initial conditions on the reservoir quickly fades. An ESP index of zero implies that the PRC possesses the echo state property.

### Memory Capacity

The memory capacity of the AO PRC should also be mentioned. Usually, longer memory is desirable for PRCs, which is accomplished through time multiplexing. For example, a nonadaptive Hopf oscillator was used as the reservoir, and the memory capacity was evaluated for a fourth-order parity task. For the nonadaptive Hopf oscillator, tens or hundreds of virtual nodes were collected using time multiplexing of the oscillator itself.

The desired goal is a parallelizable, morphable logic gate that can be implemented with the minimum number of sampled (virtual or physical) nodes, which can be reconfigured for AI inference tasks that use time multiplexing. The ω state is thus chosen as the only physical node. As can be visually observed in FIG. 25, the memory capacity of the AO is such that it can remember the single most recent input. It is noted that the AO PRC is structured to perform logic gate calculations, which necessitates one bit of memory stored in its dynamic states.

Here, only a single physical node, without time multiplexing, is sampled from the adaptive state. The AO PRC has less memory than the nonadaptive Hopf reservoir when used in this way. But, the trade-off is an approximately two orders of magnitude reduction in the number of required nodes. Thus, the described AO can be implemented at frequencies near the upper limit of the sampling rate for a dual AI inference processor that doubles as a general purpose processor.

The adaptive oscillator has been proposed as an analog reprogrammable logic gate. The adaptive oscillator has particularly interesting dynamics, as it has plastically deformable states that can calculate and store information. The reprogrammability of this logic gate is due only to the machine learning method used to train the nodal response to a target, and the adaptive oscillator itself is unmodified. This methodology highlights that time multiplexing can be completely avoided for oscillator-based physical reservoir computers by utilizing the adaptive states' dynamic response as nodes. An adaptive oscillator has been used as a physical reservoir computer without multiplexing. Further, the adaptive oscillator's unique learning ability is repurposed for generalized tasks, such as logic gates.

From a practical perspective, this oscillator-based PRC without multiplexing can provide a faster method of computation, as the number of virtual nodes (usually tens or hundreds of virtual nodes) can be reduced to a single node. This reduces the sampling requirements of the hardware. Since the transient response can be used to calculate the logic gates, the clock frequency can be considerably reduced as well, but a relatively long clock frequency was chosen here for visualization purposes. The adaptive oscillator physical reservoir computer is capable of complex artificial intelligence (AI) inference tasks, such as wake word detection, image classification, and chaotic time series prediction. By repurposing the adaptive oscillator's learning ability for logic tasks, the adaptive oscillator can provide a robust method for calculating logic gates without additional hardware considerations. Moreover, as gates can be calculated in parallel, more complex outputs can be achieved synergistically with only the hardware needed for the AI inference tasks. However, this method could also be highly consolidated as a high-performance, morphable, parallelizable logic gate architecture.

An adaptive oscillator has been presented as a physical reservoir computer. By leveraging the adaptive oscillator's intrinsic ability to learn and store information in plastic states, this physical reservoir computer has several attractive features. These features include robustness to mistuning, which is a severe limitation for limit cycle-based physical reservoir computers, and passive reprogrammability to account for the sampling rates for different use cases. This latter ability allows the adaptive oscillator physical reservoir computer to be used for real time processing of various time varying signals, and several of these examples were provided.

The ability of artificial neural network reservoir computers to predict even hidden structures in dynamical systems points to their use for time varying signal analysis. However, reservoir computing is usually computationally constrained from being performed on edge devices. The adaptive oscillator physical reservoir computer could be used as a high performance computer for edge devices, which is both robust and passively reprogrammable for disparate use cases.

Furthermore, the adaptive oscillator is proposed as an analog reprogrammable logic gate without multiplexing. The adaptive oscillator has particularly interesting dynamics, as it has plastically deformable states that can calculate and store information. The reprogrammability of this logic gate is due only to the machine learning method used to train the nodal response to a target, and the adaptive oscillator itself is unmodified. This methodology highlights that both time multiplexing and system tuning can be completely avoided for adaptive oscillator physical reservoir computers, by utilizing the adaptive states' dynamic response as nodes.

The adaptive oscillator can be used as a physical reservoir computer. The adaptive oscillator's unique learning ability can be repurposed for generalized tasks, such as logic gates. Because of the learning ability of the oscillator itself, time multiplexing can be completely avoided. From a practical perspective, this oscillator-based PRC without multiplexing can provide a faster method of computation, as the sampling rate can be considerably reduced.

The adaptive oscillator can be implemented as a physical reservoir computer. Many different oscillators can be modified to convert them to adaptive oscillators, and these adaptive oscillators can work similarly. These include the Hopf adaptive oscillator, the Duffing adaptive oscillator, the piecewise linear adaptive oscillator, the linear adaptive oscillator, and pendulum adaptive oscillator, and the van der Pol adaptive oscillator.

The adaptive states can be used to reprogram the adaptive oscillator physical reservoir computer to work with other sampling rates. This is important, as there must be a match between the resonance conditions of the oscillator and the sampling rate, which is related to the pseudo-period. Adaptive oscillators can be used as a physical reservoir computer with time multiplexing. Adaptive oscillators can be used as a physical reservoir computer without time multiplexing. The adaptive oscillator physical reservoir computer can perform generalized calculations, including time-series tasks and logic tasks.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

The term “substantially” is meant to permit deviations from the descriptive term that don't negatively impact the intended purpose. Descriptive terms are implicitly understood to be modified by the word substantially, even if the term is not explicitly modified by the word substantially.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’ includes “about ‘x’ to about ‘y’”.

1. A physical reservoir computer (PRC), comprising:
an adaptive oscillator (AO) including a dynamic plastic state adaptable to a corresponding input function, the PRC configured to utilize the dynamic plastic state to perform reconfigurable tasks.

2. The physical reservoir computer of claim 1, wherein the AO comprises a plurality of dynamic plastic states each adaptable to a corresponding input function.

3. The physical reservoir computer of claim 1, wherein the dynamic plastic state corresponds to a frequency state of an input.

4. The physical reservoir computer of claim 3, wherein the frequency state learns a resonance condition from the input.

5. The physical reservoir computer of claim 3, wherein the AO comprises a second dynamic plastic state corresponding to an amplitude state of the input.

6. The physical reservoir computer of claim 3, wherein the AO comprises a second dynamic plastic state corresponding to a phase state of the input.

7. The physical reservoir computer of claim 3, wherein the frequency state of the adaptive oscillator corresponds to a sampling rate of the desired task.

8. The physical reservoir computer of claim 1, wherein an external forcing signal based upon encoded data is injected into the AO.

9. The physical reservoir computer of claim 8, wherein the external forcing signal is generated by multiplying a sinusoid with an encoded information stream comprising the encoded data.

10. The physical reservoir computer of claim 1, wherein the PRC utilizes time multiplexing.

11. The physical reservoir computer of claim 1, wherein the PRC does not utilize time multiplexing.

12. The physical reservoir computer of claim 1, wherein the PRC is a Hopf adaptive oscillator, a van der Pol adaptive oscillator, a pendulum adaptive oscillator, a linear adaptive oscillator, a piecewise linear adaptive oscillator, a Duffing adaptive oscillator, a Rayleigh adaptive oscillator, or a neural adaptive oscillator.

13. The physical reservoir computer of claim 1, comprising a morphable logic gate wherein the AO is a single AO.

14. The physical reservoir computer of claim 13, wherein the morphable logic gate is configured to determine a plurality of logic operations without modifying circuitry of the single AO.

15. The physical reservoir computer of claim 13, wherein the morphable logic gate is configured to determine at least two of the plurality of logic operations in parallel with the single AO.

16. An analog signal processor comprising the physical reservoir computer of claim 1.

17. A reprogrammable neural network comprising the physical reservoir computer of claim 1.

18. A morphable logic gate comprising the physical reservoir computer of claim 1.
